(19) United States
(12) Patent Application Publication
(10) Pub. No.: US 2006/0043565 A1
(43) Pub. Date: Mar. 2, 2006

(54) Laser removal of plating tails for high speed packages

(76) Inventors: Chok J. Chia, Cupertino, CA (US); Seng-sooi Lim, San Jose, CA (US); Wee K. Liew, San Jose, CA (US)

Correspondence Address: LSI LOGIC CORPORATION, 1621 BARBER LANE, MS: D-106, MILPITAS, CA, 95035, US

(21) Appl. No.: 10/928,334

(22) Filed: Aug. 27, 2004

(51) Int. Cl. H01L 23/48

(52) U.S. Cl. 257/690; 257/692

(57) ABSTRACT

A method wherein a substrate with plating tails is formed or otherwise provided, such as by performing a conventional electroplating process. Subsequently, a laser is used to remove some or all of the plating tails or a portion of some or all of the plating tails. If portions or remnants of the plating tails are to remain, the plating tails can be connected to ground. By connecting the remnants of the plating tails to ground, an electrical performance enhancement can be realized. Specifically, additional shielding in the package can be provided. Furthermore, the plating tails can be specifically designed to enhance the amount of shielding they provide.

### BACKGROUND

The present invention generally relates to high speed packages, and more specifically relates to the removal of plating tails on substrates for high speed packages.

In making a high speed package, a chemical etching and electro plating processes are used to form traces on a substrate. The traces are formed to interconnect the silicon chip to pads on the package. The tips and pads of the package requires electro plating of nickel and gold or similar precious metals for interconnection by gold wire bonding to the silicon chip. The electroplating process requires the connection of all the metal traces to a common bussbar, generally on the perimeter of the package. These additional metal traces are commonly called plating tails. Plating tails are generally undesirable because they have an antenna effect, affecting the electrical performance of the package. To remove the plating tails, a chemical etching process is performed. Hence, one or more additional processing steps are performed to eliminate the plating tails which are connected to traces associated with high speed I/O's.

Alternatively, an electroless plating process is used to form the traces on the substrate. As such, no plating tails are formed during the process which must thereafter be removed in a subsequent chemical etching process. However, there is additional cost and complexity involved with electroless plating compared to electroplating.

### OBJECTS AND SUMMARY

An object of an embodiment of the present invention is to provide a simple and inexpensive method of removing plating tails (or portions of plating tails) after an electroplating process has been performed to form traces on a substrate.

Another object of an embodiment of the present invention is to provide a method of removing plating tails (or portions of plating tails) without having to perform a chemical etching process.

Still another object of an embodiment of the present invention is to provide that a substrate without plating tails can be formed, without having to form the traces using an electroless plating process and without having to perform a chemical etching process to remove the plating tails after the traces have been formed.

Briefly, and in accordance with at least one of the foregoing objects, an embodiment of the present invention provides a method wherein a substrate with plating tails is formed or otherwise provided, such as by performing a conventional electroplating process. Subsequently, a laser is used to remove some or all of the plating tails, or a portion of some or all of the plating tails.

If portions or remnants of the plating tails are to remain, the plating tails can be connected to ground. By connecting the remnants of the plating tails to ground, an electrical performance enhancement can be realized. Specifically, additional shielding in the package can be provided. Furthermore, the plating tails can be specifically designed to enhance the amount of shielding they provide.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein:

FIG. 1 provides a flow chart which illustrates a method which is in accordance with an embodiment of the present invention;

FIG. 2 illustrates a substrate with traces formed thereon, showing the situation where a portion of each of the plating tails has been removed; and

FIG. 3 is similar to FIG. 2, but illustrates the situation where the entire plating tail has been removed.

### DESCRIPTION

While the invention may be susceptible to embodiment in different forms, there are shown in the drawings, and herein will be described in detail, specific embodiments of the invention. The present disclosure is to be considered an example of the principles of the invention, and is not intended to limit the invention to that which is illustrated and described herein.

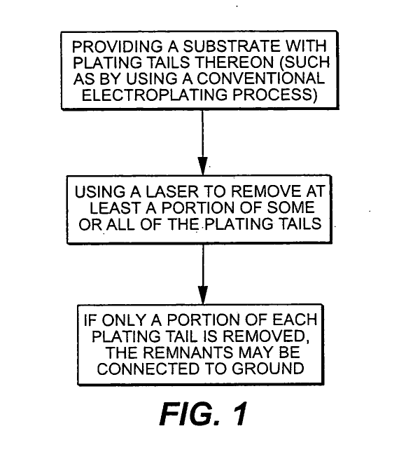

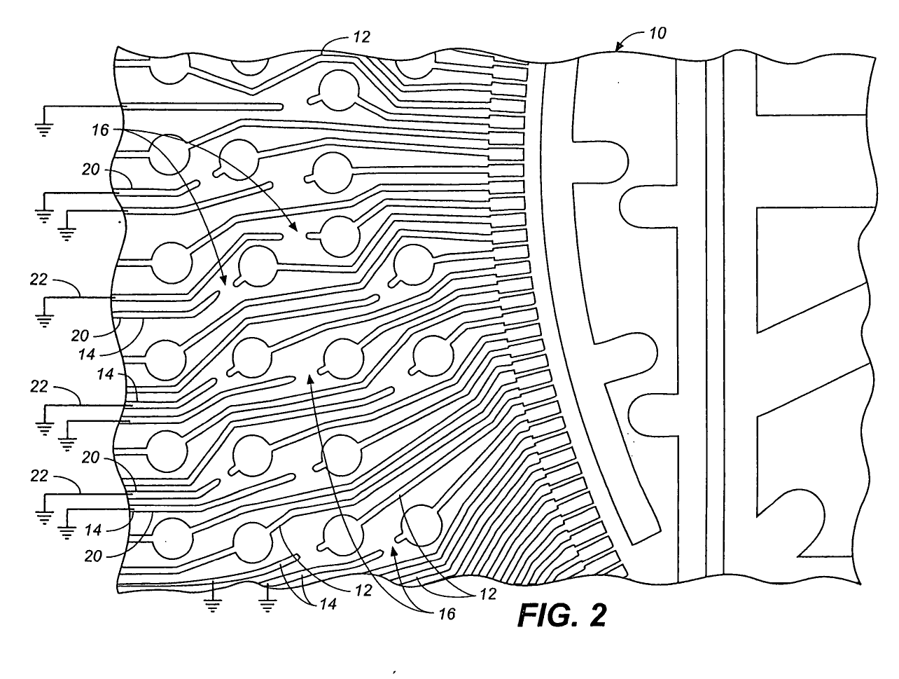

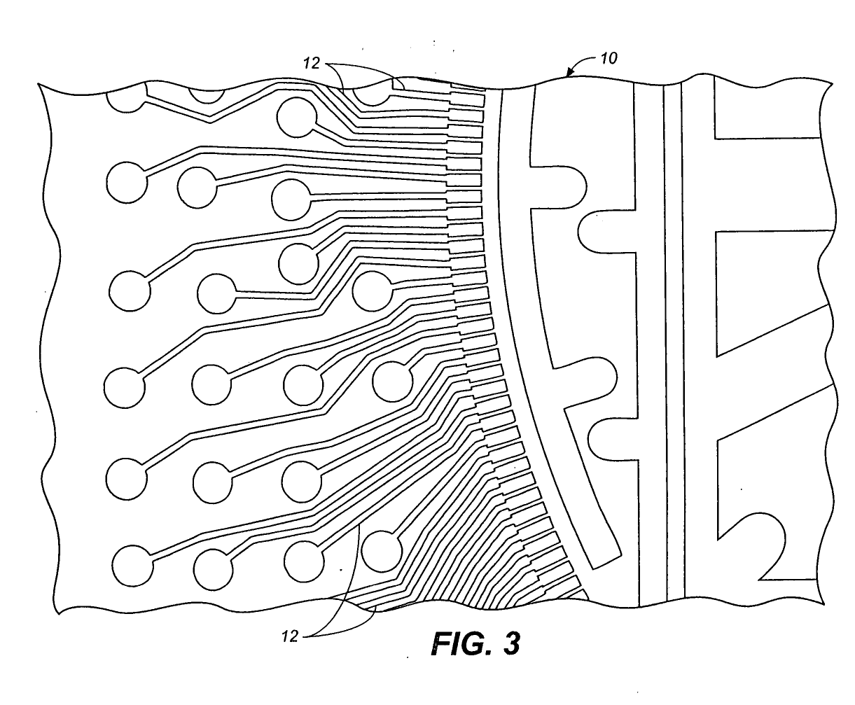

FIG. 1 illustrates a method which is in accordance with an embodiment of the present invention. The method provides that a substrate 10 (see FIGS. 2 and 3) with traces 12 and plating tails 14 is provided. To provide as such, a conventional electroplating process can be performed.

Subsequently, a laser is used to remove the plating tails 14. Specifically, a laser is used to cut away either a portion of some or all of the plating tails 14, or to remove the entire plating tail 14 (either all of the platings or just some of the plating tails). FIG. 2 shows the situation where a portion (i.e., what would be at 16) of each of the plating tails 14 on a substrate 10 has been removed with a laser. FIG. 3 shows the situation where the entire plating tail has been removed with a laser. Preferably, each of the plating tails connected to high speed I/O's are either partially or fully removed using the laser. By removing only the plating tails of the required traces, the cost of manufacturing the substrate and the package can be reduced.

By removing the entire plating tail, possible undesirable consequences associated with high speed switching can be avoided. On the other hand, if remnants 20 of the plating tails 14 are to remain as shown in FIG. 2 (i.e., the laser is used to remove only a portion of each of the plating tails 14), the remnants 20 can be connected to ground (as represented by 22 in FIG. 2) in order to realize an electrical performance enhancement. Specifically, by providing that each of the plating tail remnants 20 are connected to ground, additional shielding in the package can be provided. Furthermore, the plating tails can be specifically designed to enhance the amount of shielding they provide. Regardless, the substrate 10 which is formed may ultimately form part of a BGA (ball grid array) or other high speed package.

Not all of the plating tails need to be removed (or partially removed). For example, only selected plating tails connected to high speed signals need to be removed, thus improving the efficiency and cost of the process. The substrate can be customized for each specific application.

The present invention provides a simple and inexpensive method of removing plating tails (or portions of plating tails), without having to perform a chemical etching process. Assuming the entire plating tail is removed, the method provides that a substrate without plating tails can be provided (see FIG. 3), without having to form the traces using an electroless plating process. Assuming only portions of the plating tails are removed, and the remnants are connected to ground (see FIG. 2), the present invention can provide an electrical performance enhancement.

While embodiments of the present invention are shown and described, it is envisioned that those skilled in the art may devise various modifications of the present invention without departing from the spirit and scope of the appended claims.

1. A method of removing at least a portion of a plating tail on a substrate, said method comprising; providing the substrate with at least one plating tail thereon; and using a laser to remove at least a portion of the plating tail.

2. A method as recited in claim 1, wherein the step of using a laser to remove at least a portion of the plating tail comprises using the laser to remove the entire plating tail

3. A method as recited in claim 1, wherein the step of providing the substrate with at least one plating tail thereon comprises providing the substrate with a plurality of plating tails thereon.

4. A method as recited in claim 3, wherein the step of using a laser to remove at least a portion of the plating tail comprises using the laser to entirely remove all plating tails.

5. A method as recited in claim 3, wherein the step of using a laser to remove at least a portion or the plating tail comprises using the laser to entirely remove all plating tail which are connected to high speed signals.

6. A method as recited in claim 1, wherein the step of using a laser to remove at least a portion of the plating tail comprises using the laser to remove only a portion of the plating tail.

7. A method as recited in claim 1, wherein the stop of using a laser to remove at least a portion of the plating tail comprises using the laser to remove only a portion of each plating tail which is connected to a high speed signal.

8. A substrate comprising: a plurality of traces on the substrate and a plurality of plating tails on the substrate, spaced away from the traces such that the plating tails are not conductively connected to said traces, wherein the plating tails are non-connecting relative to each other on the substrate.

9. (canceled)
